(19) United States
(12) Patent Application Publication
(10) Pub. No.: US 2021/0249457 A1
(43) Pub. Date: Aug. 12, 2021

(54) SOLID-STATE IMAGING APPARATUS AND ELECTRONIC DEVICE

(71) Applicant: SONY SEMICONDUCTOR SOLUTIONS CORPORATION, KANAGAWA (JP)

(72) Inventor: TOMOHIKO BABA, KANAGAWA (JP)

(21) Appl. No.: 16/973,023

(22) PCT Filed: Apr. 5, 2019
(86) PCT No.: PCT/JP2019/015164

§ 371 Date: Dec. 7, 2020

(30) Foreign Application Priority Data
Jun. 15, 2018 (JP) 2018-114443
Feb. 4, 2019 (JP) 2019-018034

(51) Int. Cl. H01L 27/146; G02B 9/08

(52) U.S. Cl. CPC H01L 27/14625; G06K 9/00013; H01L 27/14627; G02B 9/08

(57) ABSTRACT

A solid-state imaging apparatus and an electronic device that are capable of improving a use efficiency of incident light while avoiding overlap of incident light among adjacent solid-state imaging devices are provided. A solid-state imaging apparatus that includes plural pixels arranged in a matrix shape on an imaging device surface, and each of the pixels includes at least one solid-state imaging device; and at least one light guiding unit that is arranged on a subject side of the solid-state imaging device, and the light guiding unit includes a first transparent body; a first lens group having a positive optical power; a light shielding unit having an opening portion; and a second lens group having a positive optical power, sequentially toward a solid-state imaging device side from the subject side along a light guiding direction of the light guiding unit is provided.

### FIELD

The present disclosure relates to a solid-state imaging apparatus and an electronic device.

### BACKGROUND

A solid-state imaging apparatus that uses a micro lens having a surface size of the same level as a unit pixel of a solid-state imaging device, and having a total length of 3 mm or smaller in place of an imaging lens (object lens) includes devices disclosed in, for example, Patent Literatures 1 and 2 described below. In the solid-state imaging apparatus as described above, plural solid-state imaging devices are closely aligned in a matrix shape on a single imaging device surface. Such a solid-state imaging apparatus is enabled to acquire an image of a subject by combining image information acquired by the respective solid-state imaging devices described above into one. Accordingly, in such a solid-state imaging apparatus, the respective solid-state imaging devices are required to detect incident light from a predetermined range without overlapping each other, and to acquire imaging information of the detected incident light and, therefore, respective pixels including respective solid-state imaging devices are preferable to have narrow angles of view that do not overlap each other.

Accordingly, to avoid the overlap as described above, in Patent Literature 1 below, two pinholes are provided between a micro lens and a solid-state imaging device, and in Patent Literature 2 below, one pinhole is provided. In Patent Literatures 1 and 2, by limiting a range of incident light detectable by each solid-state imaging device with the pinhole described above, overlap of angles of view of respective pixels is avoided.

### CITATION LIST

### Patent Literature

Patent Literature 1: Japanese Patent No. 5488928
Patent Literature 2: JP-T-2007-520743

### SUMMARY

### Technical Problem

However, in the solid-state imaging apparatus disclosed in Patent Literatures 1 and 2 above, it can be said that the use efficiency of incident light is low because the range of incident light that can be detected by the respective solid-state imaging devices is limited by pinholes.

Therefore, in the present disclosure, novel and improved solid-state imaging apparatus and electronic device that are capable of improving use efficiency of incident light while avoiding the overlap of angles of view of adjacent pixels is proposed.

### Solution to Problem

According to the present disclosure, a solid-state imaging apparatus is provided that includes: a plurality of pixels that are arranged in a matrix shape on an imaging device surface, wherein each of the pixels includes at least one solid-state imaging device; and at least one light guiding unit that is arranged on a subject side of the solid-state imaging device, wherein the light guiding unit includes a first transparent body; a first lens group having a positive optical power; a light shielding unit having an opening portion; and a second lens group having a positive optical power, sequentially toward a solid-state imaging device side from the subject side along a light guiding direction of the light guiding unit.

Moreover, according to the present disclosure, an electronic device is provided that includes a solid-state imaging apparatus that includes a plurality of pixels arranged in a matrix shape on an imaging device surface, wherein each of the pixels includes at least one solid-state imaging device; and at least one light guiding unit that is arranged on a subject side of the solid-state imaging device, wherein the light guiding unit includes a first transparent body; a first lens group having a positive optical power; a light shielding unit having an opening portion; and a second lens group having a positive optical power, sequentially toward a solid-state imaging device side from the subject side along a light guiding direction of the light guiding unit.

### Advantageous Effects of Invention

As described above, according to the present disclosure, the use efficiency of incident light can be improved while avoiding overlap of angles of view of adjacent pixels.

The effect described above is not necessarily limited, and either effect described in the present application, or other effects that can be understood from the present application may be produced in addition to the effect described above or in place of the effect described above.

### BRIEF DESCRIPTION OF DRAWINGS

FIG. 1 is a schematic diagram of a pixel 10 according to a first embodiment of the present disclosure.

FIG. 2 is a schematic diagram illustrating travel of incident light in a light guiding unit 200 illustrated in FIG. 1.

FIG. 3 is a cross-sectional schematic diagram of a solid-state imaging apparatus 1 according to the first embodiment of the present disclosure.

FIG. 4 is a planar schematic diagram of the solid-state imaging apparatus 1 according to the first embodiment of the present disclosure.

FIG. 5 is a cross-sectional schematic diagram of a solid-state imaging apparatus 1a according to a second embodiment of the present disclosure.

FIG. 6 is a cross-sectional schematic diagram of a solid-state imaging apparatus 1b according to a third embodiment of the present disclosure.

FIG. 7A is a cross-sectional schematic diagram of a solid-state imaging apparatus 1c according to a fourth embodiment of the present disclosure.

FIG. 7B is an enlarged view of a section a of FIG. 7A. FIG. 7C is an enlarged view of a section b of FIG. 7B.

FIG. 8 is a schematic diagram of a fingerprint authentication device 700 according to a fifth embodiment of the present disclosure.

FIG. 9 is a schematic diagram of a face authentication device 710 according to the fifth embodiment of the present disclosure.

FIG. 10 is an explanatory diagram for explaining a usage of the solid-state imaging apparatus 1 according to the fifth embodiment of the present disclosure.

FIG. 11 is a schematic diagram of the pixel 20 according to a comparative example,

FIG. 12A is a cross-sectional schematic diagram of a solid-state imaging apparatus 1d according to an embodiment of FIG. 6 and FIG. 7 of the present disclosure.

FIG. 12B is an enlarged view of a section c of FIG. 12A.

FIG. 13 is a schematic diagram of a pixel 10c according to an eighth embodiment of the present disclosure.

FIG. 14 is a schematic diagram of a fingerprint authentication device 700a according to the eighth embodiment of the present disclosure.

### DESCRIPTION OF EMBODIMENTS

Hereinafter, exemplary embodiments of the present disclosure will be explained in detail wither reference to the accompanying drawings. In the present application and the drawings, identical reference signs are assigned to components having substantially the same functional configurations, and duplicated explanation will be thereby omitted.

Moreover, in the present application and the drawings, components having substantially the same or similar functional configurations can be distinguished from one another by adding different numeric characters at the end of a common reference symbol. However, when it is not necessary to distinguish the respective functional components having substantially the same or similar functional configurations from one another, only the common reference symbol is used. Furthermore, similar components in different embodiments can be distinguished from one another by adding different alphabetic characters at the end of a common reference symbol. However, when it is not necessary to distinguish the respective similar components from one another, only the common reference symbol is used.

Moreover, the drawings referred to in the following explanation are drawings to facilitate explanation of an embodiment of the present disclosure and understanding thereof, and shapes, dimensions, and ratios in the drawings may differ from the actual state for easy understanding. Furthermore, the respective components in the drawings may be appropriately modified in their design, referring to the following explanation and publicly known techniques.

In the following explanation, terms “positive power” and “negative power” used for lenses indicate a power to refract a light beam by a lens, and the power varies, for example, by adjusting a refractivity and a curvature. Moreover, in the following explanation, the “positive power” out of the power of lens signifies the power to bend light to a collecting direction (inside of a lens), while the “negative power” signifies the power to bend light to a diffusing direction (outside of a lens).

Moreover, in the following explanation, a main light beam signifies incident light that passes through the center of an optical system (pixel 10 described later). Furthermore, an upper light beam signifies incident light that passes through a rim positioned at an upper side relative to a center axis of the optical system, to form an image at a solid-state imaging device, and a lower light beam signifies incident light that passes through a rim positioned at a lower side relative to the center axis of the optical system, to form an image at the solid-state imaging device.

Furthermore, in the following explanation, “angle of view” signifies a range (angle) of an image that is detected by respective pixels 10.

Explanation will be given in following order.
1. Background of Achievement of Embodiments According to the Present Disclosure by the Present Inventors
2. First Embodiment
3. Second Embodiment
4. Third Embodiment
5. Fourth Embodiment
6. Fifth Embodiment
7. Sixth Embodiment
8. Seventh Embodiment
9. Eighth Embodiment
10. Conclusion
11. Supplement

### 1. Background of Achievement of Embodiments According to the Present Disclosure by the Present Inventors

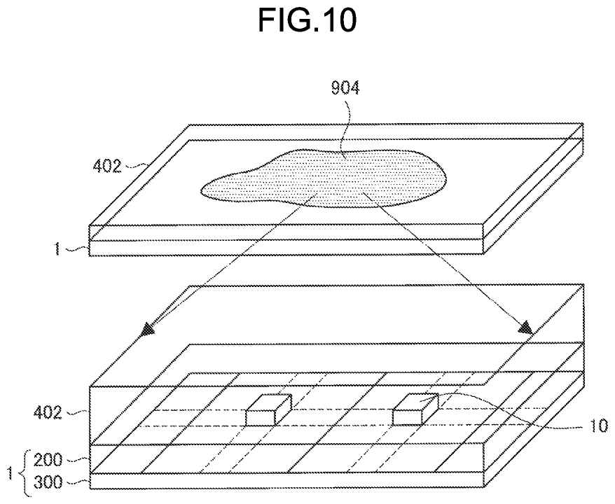

Next, before explaining details of respective embodiments according to the present disclosure, the background of achievement of embodiments according to the present disclosure by the present inventors will be explained, referring to FIG. 11. FIG. 11 is a schematic diagram of a pixel 20 according to a comparative example. The comparative example means a configuration of a solid-state imaging apparatus that had been studied before the achievement of the embodiments of the present disclosure by the present inventors, and in more details, signifies a configuration that is not a Keplerian optical system.

As explained previously, examples of a solid-state imaging apparatus that uses a micro lens having a surface size of the same level as a unit pixel of a solid-state imaging device instead of an imaging lens (object lens) include, for example, apparatuses disclosed in Patent Literature 1 and 2 described above. In the solid-state imaging apparatus as described above, plural solid-state imaging devices are closely aligned in a matrix shape on a single imaging device surface. Such a solid-state imaging apparatus is enabled to acquire an image of a subject by combining image information acquired by the respective solid-state imaging devices described above into one. Accordingly, in such a solid-state imaging apparatus, the respective solid-state imaging devices are required to detect incident light from a narrow predetermined range without overlapping each other, and to acquire imaging information of the detected incident light and, therefore, respective pixels including respective solid-state imaging devices are configured to have narrow angles of view that do not overlap each other.

Specifically, the solid-state imaging apparatus according to the comparative example include plural pixels 20 arranged closely to each other as illustrated in FIG. 11. The respective pixels 20 includes solid-state imaging devices 300a, 300b, and a light guiding unit 202 to guide light from a subject to the respective solid-state imaging devices 300a, 300b. In FIG. 11, a left side is a subject side.

In FIG. 11, the solid-state imaging device 300a detects not only incident light 600a indicated by solid lines (indicated by three lines of a main light beam, and an upper light beam and a lower light beam sandwiching the main light beam), but also incident light 600b indicated by alternate long and two short dashes lines (indicated by three lines of a main light beam, and an upper light beam and a lower light beam sandwiching the main light beam). It is assumed that the incident light 600b has the main light beam at an angle of about 5 degrees relative to the main light beam of the incident light 600a.

In such a case, specifically, the incident light 600a reaches the solid-state imaging device 300a without deviating from the light guiding unit 202 of the solid-state imaging device 300a. On the other hand, the incident light 600b passes through the light guiding unit 202 of the solid-state imaging device 300b to which the lower light beam thereof is adjacent, and reaches the solid-state imaging device 300a. The lower light beam of this incident light 600b is incident light that is supposed to be detected originally by the solid-state imaging device 300b adjacent thereto. When incident light that is supposed to be originally detected by the adjacent solid-state imaging device 300b is detected by the solid-state imaging device 300a as in this case, imaging information of the incident light detected by the solid-state imaging devices 300a, 300b includes a part overlapping each other. As a result, in such a case, even if the imaging information acquired by the respective solid-state imaging devices 300a, 300b are combined into one, a false image different from an actual image of the subject is to be acquired. Accordingly, to avoid such a problem, it is desired that the lower light beam of the incident light 600b that enters the solid-state imaging device 300a is cut off, and the pixels 20 according to the respective solid-state imaging devices 300a, 300b be adjusted to have predetermined angles of view that do not overlap each other.

Therefore, in the solid-state imaging apparatus disclosed in Patent Literatures 1, 2 described above, by limiting incident light that enters respective solid-state imaging devices from multiple directions by applying pinholes, it is adjusted such that respective pixels have predetermined angles of view not overlapping each other. However, in the solid-state imaging apparatus disclosed in Patent Literature 1 and 2 described above, because the ranges in which incident light is detectable by the respective solid-state imaging devices are limited with the pinholes, the use efficiency of incident light is low.

In view of such a situation, the present inventors diligently studied whether the use efficiency of incident light can be improved while avoiding overlap of angles of view of adjacent pixels. While such a study is being carried out, the present inventors have uniquely conceived an idea of using a Keplerian optical system that once forms an image before forming an image in a solid-state imaging device in a light guiding unit that guides light to the solid state imaging device.

Specifically, in a comparative example that is not a Keplerian optical system, according to the study of the present inventors, as illustrated in FIG. 11, the incident light 600a and the incident light 600b from an image on an imaging device surface 502 of the solid-state imaging device 300a. When the lower light beam of the incident light 600b that enters the solid-state imaging device 300a is to be cut off by using a pinhole or the like, it is preferable to cut off light at a position of the image formation described above at which overlap of the incident light 600a and the incident light 600b is small. However, as it is shown in FIG. 11, positions of image formation by the incident light 600a and the incident light 600b are significantly close to each other and, therefore, the incident light 600a and the incident light 600b overlap each other also near the imaging device surface 502. Accordingly, when the lower light beam of the incident light 600b is to be cut off on the imaging device surface 502, at least a part of the incident light 600a that is supposed to be originally detected by the solid-state imaging device 300a can be cut off.

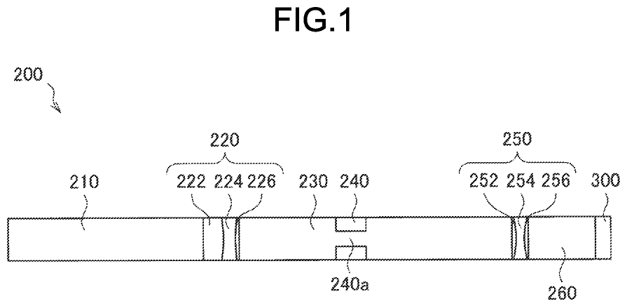

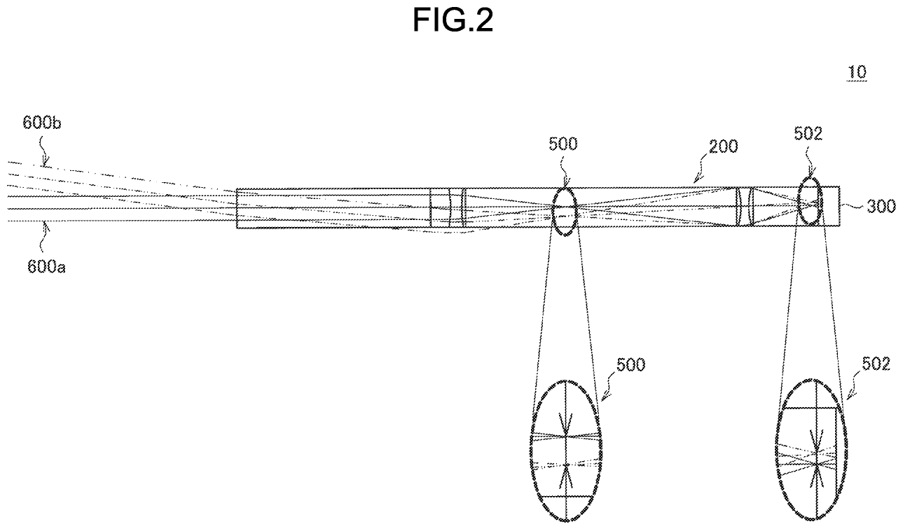

On the other hand, according to the study of the present inventors, when a Keplerian optical system is used to form an image once in a previous stage before forming an image by the solid-state imaging device 300, although details are described later (refer to arrows in FIG. 2), it was found that positions of image formation of the incident light 600a, 600b in the previous stage can be separated further than the comparative example described above. Based on this original finding, the present inventors have uniquely conceived that the lower light beam of the incident light 600b can be cut off without cutting off the incident light 600a supposed to be originally detected by the solid-state imaging device 300a by providing a light shielding unit 240 (refer to FIG. 1) at a position at which image formation occurs at a position short thereof.

That is, based on the original findings described above, the present inventors have thought of a solid-state imaging apparatus that is capable of improving the use efficiency of the incident light 600a as the incident light 600a that is supposed to be originally detected by the solid-state imaging device 300a is not cut off while avoiding overlap of angles of view of the adjacent pixels 20 by using a Keplerian optical system. In other words, the present inventors have achieved embodiments of a solid-imaging apparatus that uses a micro lens having a surface size of the same level as a unit pixel of a solid-state imaging device, and having a total length of 3 mm or smaller, not using an imaging lens (object lens), and that is capable of improving the use efficiency of incident light while avoiding overlap of angles of view of adjacent pixels. Hereinafter, the embodiments according to the present disclosure will be sequentially explained in detail.

### 2. First Embodiment

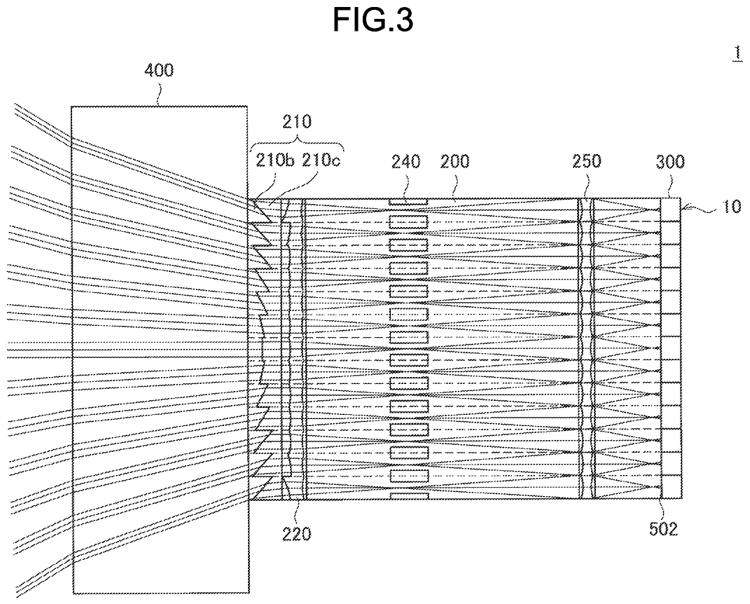

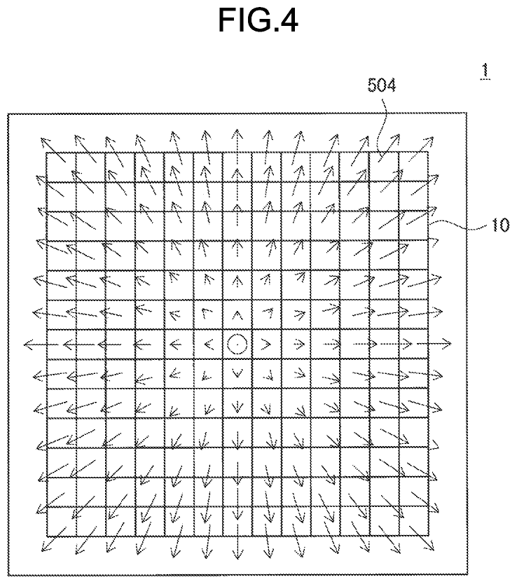

First, a solid-state imaging apparatus 1 according to a first embodiment of the present disclosure will be explained, referring to FIG. 1 to FIG. 4. FIG. 1 is a schematic diagram of a pixel 10 according to the present embodiment, and FIG. 2 is a schematic diagram illustrating travel of incident light in a light guiding unit 200 illustrated in FIG. 1. Furthermore, FIG. 3 is a cross-sectional schematic diagram of the solid-state imaging apparatus 1 according to the present embodiment, and FIG. 4 is a planar schematic diagram of the solid-state imaging apparatus 1 according to the present embodiment. Note that a left side in the drawings is a subject side through FIG. 1 to FIG. 3.

Specifically, the solid-state imaging apparatus 1 is an apparatus that detects visible light from a subject side to image the subject. On an imaging device surface (imaging surface) of the solid-state imaging apparatus 1, plural unit cells are arranged in a two-dimensional lattice shape (matrix). The unit cells are units that constitute the solid-state imaging apparatus 1, and are referred to as pixels 10 in the following explanation, and respectively generate pixel data in captured image data. Moreover, each of the pixels 10 includes, as illustrated in FIG. 1, at least one piece of the solid-state imaging device 300, and at least one unit of the light guiding unit 200 arranged on the subject side of the solid-state imaging device 300.

The solid-state imaging device 300 is, for example, a charge coupled device (CCD) image sensor or a complementary metal-oxide-semiconductor (CMOS) image sensor, and photoelectric converts received light to generate an analog electrical signal. The generated electrical signal is converted into digital pixel data in captured image data by using a processing circuit and the like.

Moreover, the light guiding unit 200 arranged on the subject side of the solid-state imaging device 300 can guide light to the solid-state imaging device 300. In the following explanation, a light guiding direction of the light guiding unit 200 is a direction toward right from left in FIG. 1, that is, a direction to which the light guiding unit 200 guides incident light to the solid-state imaging device 300. Moreover, in the following explanation, “length” is length along the light guiding direction unless otherwise specified.

Specifically, the light guiding unit 200 includes, as illustrated in FIG. 1, a transparent body (first transparent body) 210, a lens group (first lens group) 220 having a positive optical power, a light shielding unit 240, and a lens group (second lens group) 250 having a positive optical power, sequentially from the subject side to the solid-state imaging device 300 side. In the present embodiment, the light guiding unit 200 forms a Keplerian optical system that focuses once between the lens group 220 and the lens group 250 (refer to FIG. 2). Therefore, a distance L between the lens group 220 and the lens group 250 is required to be larger than a sum of a focal length fg₁ of the lens group 220 and a focal length fg₂ of the lens group 250.

Furthermore, it is assumed that the transparent body 210 on the subject side has a negative power. In such a case, an image formed by the lens group 220 is to be formed at a position at a shorter distance than the focal length fg₁. In addition, it is assumed to be long because while the focal length fg₂ of the lens group 250 is subject to limitation by a surface size of the pixel 10, the focal length fg₁ is not subject to such limitation. Therefore, in the present embodiment, based on the above description, it is preferable that the focal length fg₁ of the lens group 220, the focal length fg₂ of the lens group 250, and the distance L between the lens group 220 and the lens group 250 satisfy a condition expression (a) below to form a Keplerian optical system that focuses once between the lens group 220 and the lens group 250.

L<(fg₁+fg₂)/2 (a)

In the present embodiment, as illustrated in FIG. 1, the light shielding unit 240 having an opening portion 240a that overlaps a focal point positioned between the lens group 220 and the lens group 250 to cut off light is provided.

Moreover, in the solid-state imaging apparatus 1 according to the present embodiment, it is preferable to structure the light guiding unit 200 such that a range of an angle of incident light that enters the pixel 10 positioned at the center of the imaging device surface (imaging surface) satisfies a condition expression (b) below. Specifically, in the solid-state imaging apparatus 1 according to the present embodiment, it is preferable that a range of an angle θ formed by the upper light beam and the lower light beam entering the pixel 10 that is positioned at the center of the imaging device surface satisfy the condition expression (b) below. Note that in the condition expression (b), a light collecting direction takes a negative value, and a light diffusing direction takes a positive value.

−10°≤θ≤10° (b)

More specifically, as explained previously, in the solid-state imaging apparatus 1, the respective pixels 10 are desired to be adjusted to have a predetermined angle of view, not overlapping the adjacent pixel 10. To avoid the overlap as described above, it is preferable that the angle θ formed between the upper light beam and the lower light beam be, for example, 10° or smaller.

Moreover, a use of the solid-state imaging apparatus 1 bringing the subject close thereto is also assumed. When the subject is brought significantly close thereto, the angle θ formed between the upper light beam and the lower light beam is to be the light collecting direction, that is, a negative value. Furthermore, when it is used bringing the subject close to the solid-state imaging apparatus 1, it is assumed that a cover glass 400 (refer to FIG. 3) or a protection film is arranged to protect the light guiding unit 200. Therefore, there is a possibility that the length of the light guiding unit 200 becomes shorter than a distance from the subject to the light guiding unit 200. In addition, it is difficult to manufacture a high power micro lens. Therefore, in the present embodiment, when the optical characteristics of glass to form the cover glass 400 and the like are considered based on the above description, the angle θ formed between the upper light beam and the lower light beam is preferable to be, for example, −10° or more.

Furthermore, in the present embodiment, the range of the angle θ formed between the upper light beam and the lower light beam entering the pixel 10 that is positioned at the center of the imaging device surface is more preferable to be −2°≤θ≤2°.

Furthermore, in the present embodiment, the focal length fg₂ of the lens group 250 is preferable to satisfy a condition expression (c) below.

3 mm>fg₂>0.0005 mm (c)

Specifically, in the solid-state imaging apparatus 1 according to the present embodiment, the plural pixels 10 are assumed to be in a size of several mm or smaller, and about 0.6 μm or larger. Accordingly, because it is subject to limitation by such a size of the pixel 10, the focal length fg₂ of the lens group 250 is assumed to be larger than 0.0005 mm. Moreover, in the solid-state imaging apparatus 1 according to the present embodiment, the length of the light guiding unit 200 is assumed to be 3 mm or smaller, considering that the light guiding unit 200 is included in the pixel 10. Therefore, in the present embodiment, the focal length fg₂ of the lens group 250 is required to be smaller than 3 mm.

Furthermore, in the present embodiment, the focal length fg₂ of the lens group 250 is preferable to be 1 mm>fg₂>0.0003 mm.

Next, an effect of the light guiding unit 200 according to the present embodiment as described, that is, how light travels in the light guiding unit 200, will be explained, referring to FIG. 2. In FIG. 2, illustration of the light shielding unit 240 is omitted for easy understanding.

FIG. 2 illustrates the two incident light 600a, 600b. Specifically, as the incident light 600a, the upper light beam and the lower light beam having the main light beam in the center are illustrated together with the main light beam perpendicular to the imaging device surface of the solid-state imaging device 300. Moreover, as the incident light 300b, the upper light beam and the lower light beam having the main light beam in the center are illustrated together with the main light beam that is at an angle of about 5 degrees relative to the main light beam of the incident light 600a. The lower light beam of the incident light 600b should be detected by the adjacent solid-state imaging device 300 because it deviates from the light guiding unit 200, and is, in other words, incident light to be cut off.

As illustrated in FIG. 2, in the present embodiment, because it is the Keplerian optical system that focuses once between the lens group 220 and the lens group 250, the incident light 600a and the incident light 600b form an image at an imaging forming position 500. According to the study of the present inventors, image formation of the incident light 600a and image formation of the incident light 600b can be separated by about 2.3 μm at the image forming position 500. On the other hand, as illustrated in FIG. 2, on the imaging device surface 502 at which image is formed again, image formation of the incident light 600a and image formation of incident light 600b are separated only by 0.6μ m.

Specifically, on the imaging device surface 502, the image formation of the incident light 600a and the image formation of the incident light 600b are significantly close to each other, and the incident light 600a and the incident light 600b overlap each other. Therefore, when the incident light 600b is to be cut off on the imaging device surface 502, at least a part of the incident light 600a that is supposed to be originally detected by the solid-state imaging device 300 can be cut off, and in such a case, the use efficiency of the incident light 600a can be reduced. Moreover, it can be considered to cut off the incident light 600b on the subject side (left side of the pixel 10) also, because the incident light 600a and the incident light 600b overlap each other on the subject side also, at least a part of the incident light 600a can be cut off.

On the other hand, in the present embodiment, at the image forming position 500, the image formation of the incident light 600a and the image formation of the incident light 600b are sufficiently separated from each other. Therefore, by providing the light shielding unit 240 at the image forming position 500, the incident light 600b can be cut off without cutting off the incident light 600a that should originally be detected by the solid-state imaging device 300. That is, according to the present embodiment, in the solid-state imaging apparatus 1 that uses a micro lens having a surface size of the same level as a unit pixel of a solid-state imaging device, not using an imaging lens, the use efficiency of the incident light 600a can be improved while avoiding the overlap of the angles of view of the adjacent pixels 10.

More specifically, as illustrated in FIG. 1, the light guiding unit 200 includes the transparent body 210. The transparent body 210 is a transparent body, for example, having a d-line refractivity of 1.5 and a length of 50 μm.

The lens group 220 includes a micro lens (first micro lens) 222 having a convex shape toward the solid-state imaging device 300 side, a micro lens (second micro lens) 226 having a convex shape toward the subject side, and a transparent body (fourth transparent body) 224 that is arranged between the micro lens 222 and the micro lens 226. More specifically, the micro lens 222 is made of, for example, a lens material having a d-line refractivity of 1.9 and a thickness of 5 μm, and a curvature of the lens is −15 μm. The micro lens 226 is made of, for example, a lens material having a d-line refractivity of 1.9 and a thickness of 1 μm, and a curvature of the lens is 15 μm. Moreover, the transparent body 224 is a transparent body having, for example, a d-line refractivity of 1.48 and a thickness of 3 μm. The micro lenses 222, 226 may be implemented by a diffraction element, or the like.

Moreover, the light guiding unit 200 includes a transparent body (second transparent body) 230 between the lens group 220 and the lens group 250. Specifically, the transparent body 230 is a transparent body having, for example, a d-line refractivity of 1.55 and a length of 70 μm. Moreover, in the transparent body 230, the light shielding unit 240 described above is arranged. The light shielding unit 240 is an open light shielding body having the opening portion 240a at a center as explained previously.

Furthermore, the lens group 250 includes a micro lens (fourth micro lens) 252 having a convex shape toward the solid-state imaging device 300 side, a micro lens (third micro lens) 256 having a convex shape toward the subject side, and a transparent body (fifth transparent body) 254 that is arranged between the micro lens 252 and the micro lens 256. More specifically, the micro lens 252 is made of, for example, a lens material having a d-line refractivity of 1.9 and a thickness of 1 μm, and a curvature of the lens is −7 μm. The micro lens 256 is made of, for example, a lens material having a d-line refractivity of 1.9 and a thickness of 1 μm, and a curvature of the lens is 7 μm. Moreover, the transparent body 254 is, for example, a transparent body having a d-line refractivity of 1.48 and a thickness of 2 μm. The micro lenses 252, 256 may be implemented by a diffraction element, or the like.

Furthermore, the light guiding unit 200 further includes a transparent body (third transparent body) 260 between the lens group 250 and the solid-state imaging device 300. Specifically, the transparent body 260 is, for example, a transparent body having a d-line refractivity of 1.55 and a length of 17 μm.

The lens materials and the transparent bodies described above may be formed with SiO₂, SiN, glass, or the like.

That is, in the present embodiment, the light guiding unit 200 is preferable to be buried in a transparent medium other than air, through the transparent body 210 on the subject side to the solid-state imaging device 300.

Details of the solid-state imaging apparatus 1 constituted of plural pieces of the pixels 10 aligned as described will be explained, referring to FIG. 3 and FIG. 4. As illustrated in FIG. 3, plural pieces of the pixels 10 are aligned, and the cover glass 400 is arranged on the plural pixels 10 on the subject side. In other words, the cover glass 400 is arranged on a surface of the transparent body 210 on the subject side in a shared manner among the plural pixels 10. Moreover, the cover glass 400 is made of, for example, a glass material having a d-line refractivity of 1.55 and a thickness of 45 μm.

Moreover, in FIG. 3, the transparent body 210 described above is constituted of two transparent bodies 210b, 210c. Specifically, the transparent body 210b is, for example, a transparent body having a d-line refractivity of 1.55 and a thickness of 5 μm, and the transparent body 210c is, for example, a transparent body having a d-line refractivity of 1.9 and 5 μm, and a function of refracting the main light beam. Because other elements of the light guiding unit 200 are similar to those of the light guiding unit 200 in FIG. 1 described above, explanation is omitted herein.

In FIG. 3, for example, 13 pieces of the pixels 10 are aligned in a vertical direction, and optical axes passing through the center of an angle of view of the respective pixels 10 are inclined at −31.3°, −25.1°, −19.8°, −14.8°, −9.9°, −4.6°, 0°, 4.9°, 9.9°, 14.8°, 19.8°, 25.1°, 31.3° relative to an optical axis (the optical axis is perpendicular to the imaging device surface) passing through the center of the angle of view of the pixel 10 that is positioned at the center of the imaging device surface 502. In the present embodiment, by giving inclinations as described above, the solid-state imaging apparatus 1 having desirable angle of view as a whole with the plural pixels 10 can be configured. For example, the length of one side of the imaging device surface 502 on which the plural solid-state imaging devices 300 are aligned is approximately 152.2 μm.

In the present embodiment, as illustrated in FIG. 3, the respective transparent bodies 210c are preferable to be arranged such that surfaces of the transparent bodies 210c that have a function of refracting the main light beam inclined at −41°, −41°, −41°, −34.5°, −25.5°, −12.75°, 0°, 12.75°, 25.5°, 34.5°, 41.4°, 41, 41°, 41° sequentially from a top of the drawing. Furthermore, in the present embodiment, by the micro lens 222 of the lens group 220 of the pixel 10 positioned at the top in FIG. 3, the incident light is decentered 4.8 μm upward, and by the micro lens 222 of the lens group 220 of the second pixel 10 from the top in FIG. 3, the incident light is decentered 2.4 μm upward. By the micro lens 222 of the lens group 220 of the second pixel 10 from the bottom in FIG. 3, the incident light is decentered 2.4 μm downward, and by the micro lens 222 of the lens group 220 of the pixel 10 at the bottom in FIG. 3, the incident light is decentered 4.8 μm downward. As a result, according to the present embodiment, the solid-state imaging apparatus 1 having a desirable angle of view as a whole with the plural pixels 10 can be configured. That is, the solid-state imaging apparatus 1 according to the present embodiment can function as an imaging device (camera) having a predetermined angle of view even with out an imaging lens (object lens).

That is, in the present embodiment, the respective transparent bodies 210c are arranged such that the surfaces of the transparent bodies 210c on the subject side have different angles relative to the imaging device surface 502 in each of the pixels 10. Moreover, in the present embodiment, in the present embodiment, the respective micro lenses 222 are arranged such that surfaces of the micro lenses 222 on the solid-state imaging device 300 side have different angles relative to the imaging device surface 502 in each of the pixels 10. Specifically, in the present embodiment, by giving inclinations to the surfaces of the transparent bodies 210c on the subject side and the surfaces of the micro lenses 222 on the solid-state imaging device 300 side sequentially for each position of the pixels 10, the incident light is refracted. As the incident light is refracted on the surfaces of different inclinations, angles of the main light beams differ from each other in each of the pixels 10, and the solid-state imaging apparatus 1 having a desirable angle of view as a whole with the plural pixels 10 can be configured. In the present embodiment, the transparent bodies 210c and the surfaces of the micro lenses 222 may be arranged so as to have different angles relative to the imaging device surface 502, not every single piece of the pixels 10, but every predetermined number of the pixels 10. Moreover, in the present embodiment, the incident light may be refracted, for example, by using differences in refractivity of the transparent bodies 210b, 210c, not by refracting the incident light by the angle of the surfaces.

In the present embodiment, as explained previously, the incident light form an image once between the lens group 220 and the lens group 250, and form an image again on the imaging device surface 502 of the solid-state imaging device 300. Moreover, one piece of the pixel 10 has an optical axis perpendicular to the imaging device surface 502 of the solid-state imaging device 300 included in the relevant pixel 10 at least between the surface on the solid-state imaging device 300 side and the solid-state imaging device 300.

Next, a planner configuration of the solid-state imaging apparatus 1 according to the present embodiment will be explained, referring to FIG. 4. In FIG. 4 small rectangles express the respective pixels 10, and arrows 504 indicate directions of optical axis that pass through the center of an angle of view. In FIG. 4, the solid-state imaging apparatus 1 in which 13 pieces of the pixels 10 are aligned each along a vertical direction and a horizontal direction is illustrated, but in the present embodiment, the number of the pixels 10 or arrangement thereof are not limited to the form illustrated in FIG. 4, and are selectable as appropriate.

In the explanation described above, the pixel 10 has been explained to have a single piece of the solid-state imaging device 300 and a single piece of the light guiding unit 200, but in the present embodiment, it is not limited thereto, and the pixel 10 may include plural pieces of the solid-state imaging devices 300 and light guiding units 200. In this case, the plural pieces of the solid-state imaging devices 300 in a single piece of the pixel 10 are to have a common main light beam.

As described, according to the present embodiment, the use efficiency of incident light can be improved while avoiding overlap of angles of view of the adjacent pixels 10 in the solid-state imaging apparatus 1 the uses a micro lens having a surface size of the same level as a unit pixel of a solid-state imaging device, instead of an imaging lens (object lens).

Moreover, according to the present embodiment, because an imaging lens (object lens) is not used, it becomes possible to manufacture, at low cost, a solid-state imaging apparatus to detect an infrared ray that is difficult to use a general imaging lens. Furthermore, according to the present embodiment, because an imaging lens is not used, the solid-state imaging apparatus 1 without chromatic aberration can be provided. For example, when the present embodiment is applied to the solid-state imaging apparatus 1 that detects an infrared ray and visible light, it is possible to suppress occurrence of a focus difference between an infrared ray and visible light.

Moreover, because the solid-state imaging apparatus 1 according to the present embodiment does not include an imaging lens, it can be manufactured in a semiconductor manufacture process. Consequently, according to the present embodiment, increase of manufacturing cost can be suppressed.

### 3. Second Embodiment

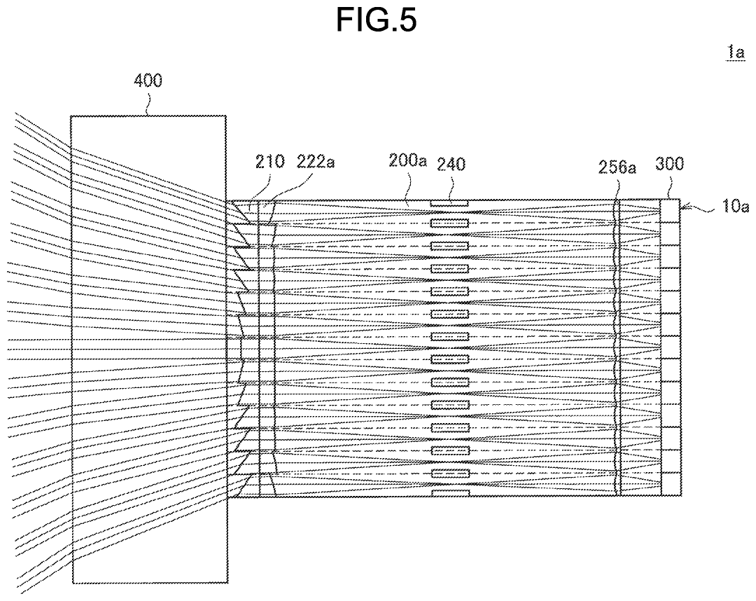

Next, a solid-state imaging apparatus 1a according to a second embodiment of the present disclosure will be explained, referring to FIG. 5. FIG. 5 is a cross-sectional schematic diagram of the solid-state imaging apparatus 1a according to the present embodiment.

In the first embodiment described above, together with the lens groups 220 and 250, two pieces each of the micro lenses 222, 226, 252, 256 are included. On the other hand, in the present embodiment, as illustrated in FIG. 5, instead of the lens groups 220, 250 according to the first embodiment, one piece each of micro lens 222a, 256a are included. Specifically, the micro lens 222a corresponds to the micro lens 222 of the lens group 220 according to the first embodiment, and the micro lens 256a corresponds to the micro lens 256 of the lens group 250 according to the first embodiment. In the second embodiment, points except the points described above are common to the first embodiment, and a light guiding unit 200a serves as an Keplerian optical system that focuses between the micro lens 222a and the micro lens 256a, similarly to the first embodiment. In the present embodiment, an effect of the light guiding unit 200a is similar to that of the first embodiment and, therefore, detailed explanation is omitted herein. The micro lenses 222a, 256a may be implemented by a diffraction element, or the like, similarly to the first embodiment.

### 4. Third Embodiment

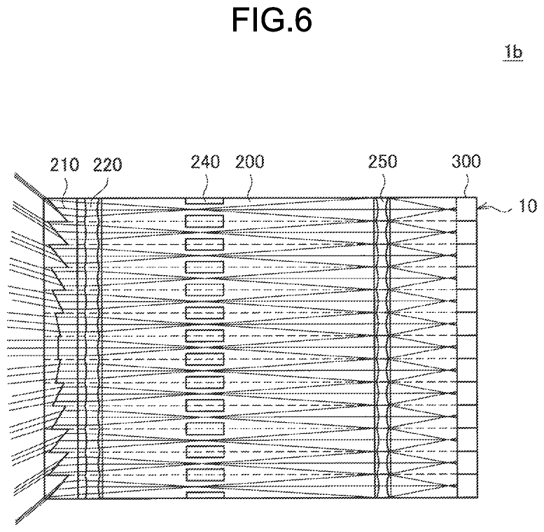

Next, a solid-state imaging apparatus 1b according to a third embodiment of the present disclosure will be explained, referring to FIG. 6. FIG. 6 is a cross-sectional schematic diagram of the solid-state imaging apparatus 1b according to the present embodiment.

In the first embodiment described above, the cover glass 400 is used to protect the light guiding unit 200. On the other hand, in the present embodiment, as illustrated in FIG. 6, the cover glass 400 is not required to be provided, and incident light may enter directly to the light guiding unit 200 from atmosphere, and the incident light may be refracted by the transparent body 210 or the like. The third embodiment is common to the first embodiment except the points described above, and the light guiding unit 200 serves as a Keplerian optical system that focus between the lens group 220 and the lens group 250 similarly to the first embodiment. An effect of the light guiding unit 200 in the present embodiment is similar to that of the first embodiment and, therefore, detailed explanation thereof is omitted herein.

### 5. Fourth Embodiment

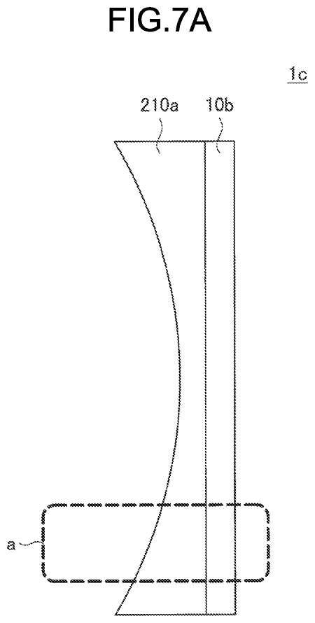

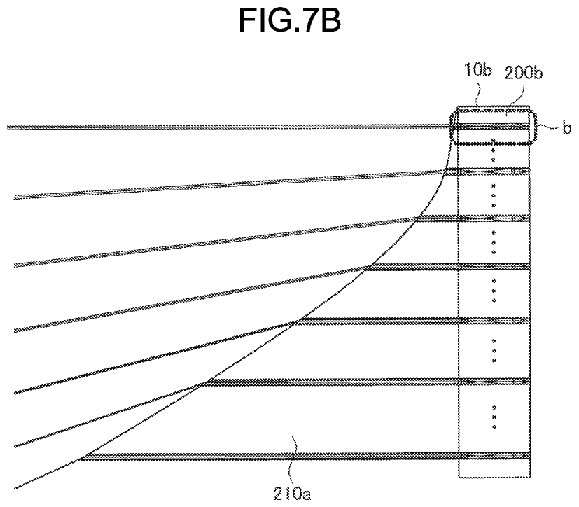

Furthermore, a solid-state imaging apparatus 1c according to a fourth embodiment of the present disclosure will be explained, referring to FIG. 7A to FIG. 7C. FIG. 7A is a cross-sectional schematic diagram of the solid-state imaging apparatus 1c according to the present embodiment. FIG. 7B is an enlarged view of a section a of FIG. 7A, and FIG. 7C is an enlarged view of a section b of FIG. 7B.

In the third embodiment described above, the solid-state imaging apparatus 1b includes plural pieces of the transparent bodies 210 having a function of refracting the main light beam directly entering from atmosphere. On the other hand, in the present embodiment, the solid-state imaging apparatus 1c includes a single lens having continuous concave surface in which plural pieces of the transparent bodies 210 are formed in one piece.

As illustrated in FIG. 7A, in the present embodiment, as a common transparent body 210a to plural pieces of pixels 10c, a lens having a concave surface (concave shape) is provided. Specifically, as illustrated in FIG. 7B, which is an enlarge view of a section a of FIG. 7A, plural pieces of pixels 10b are aligned, and the transparent body 210a common to the plural pieces of the pixels 10b have a concave surface on the subject side so as to sequentially refract the main light beam of the respective pixels 10b. In the present embodiment, the transparent body 210a is a transparent body having a curvature radius of 4.1 mm, and includes 400 pieces×533 pieces of the solid-state imaging devices 300 aligned, on a surface having the maximum radius of 2 mm within a range of 2.4 mm×3.2 mm in length and width. Furthermore, the respective pixels 10b have a light guiding unit 200b as illustrated in FIG. 7C, which is an enlarged view of a section b of FIG. 7B. In the fourth embodiment, points except the points described above are common to the first embodiment, the light guiding unit 200b serves as a Keplerian optical system that focuses between the lens group 220 and the lens group 250 similarly to the first embodiment. An effect of the light guiding unit 200b in the present embodiment is similar to that of the first embodiment and, therefore, detailed explanation thereof is omitted herein. According to the present embodiment, by configuring as described, for example, the solid-state imaging apparatus 1c having the maximum angle view of 40° with 213 thousand pixels can be formed.

### 6. Fifth Embodiment

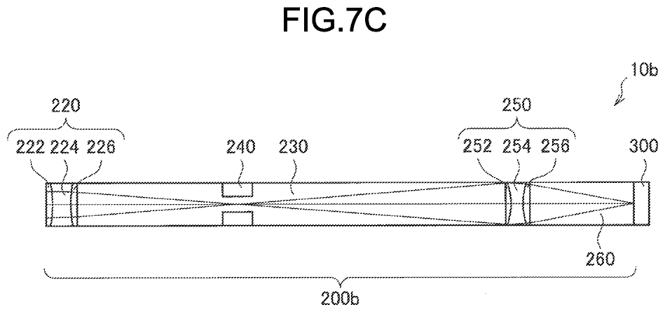

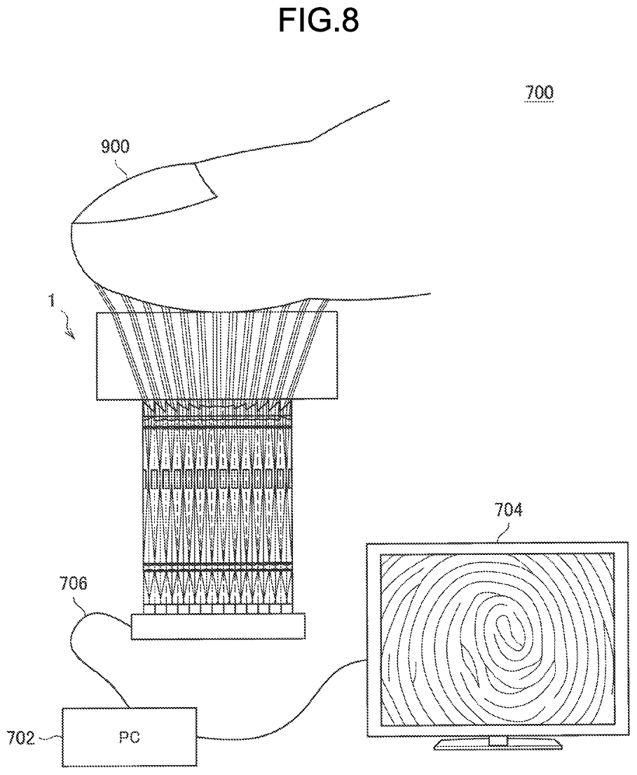

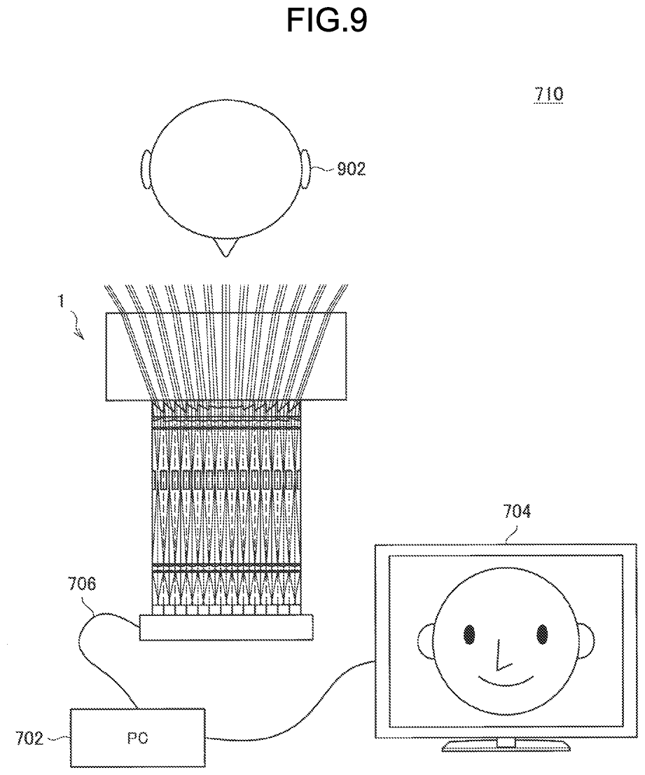

The solid-state imaging apparatus 1 according to the respective embodiments of the present disclosure described above can be applied to an electronic device, such as a fingerprint authentication device 700, a face/iris authentication device 710, and a research observation device. An application example of the solid-state imaging apparatus 1 according to the present embodiment will be explained, referring to FIG. 8 to FIG. 10. FIG. 8 is a schematic diagram of the fingerprint authentication device 700 according to the present embodiment, and FIG. 9 is a schematic diagram of the face authentication device 710 according to the present embodiment. Furthermore, FIG. 10 is an explanatory diagram for explaining a usage of the solid-state imaging apparatus 1 according to the present embodiment, and specifically, is an explanatory diagram for explaining a case in which the solid-state imaging apparatus 1 is applied to a research observation device.

First, the fingerprint authentication device 700 according to the present embodiment will be explained, referring to FIG. 8. The fingerprint authentication device 700 is a device that performs fingerprint authentication, and includes the solid-state imaging apparatus 1 according to the present embodiment as a fingerprint sensor unit that detects a fingerprint. Furthermore, the fingerprint authentication device 700 includes a processing unit 702 and a display unit 704. The processing unit 702 is a device that performs authentication with respect to a fingerprint detected by the solid-state imaging apparatus 1, and is implemented, for example, by a personal computer. Moreover, the display unit 704 is a device that displays a fingerprint detected by the solid-state imaging apparatus 1 or an authentication result, and is implemented, for example, by a cathode ray tube (CRT) display device, a liquid crystal display (LCD) device, an organic light emitting diode (OLED) device, and the like.

Specifically, the solid-state imaging apparatus 1 images a fingerprint of a finger 900 in accordance with a control by the processing unit 702, and transmits image data to the processing unit 702 through a data line 706. The processing unit 702 compares the received image data and registration information that is an image of a fingerprint that has been registered in the processing unit 702 in advance, to determine success or failure of authentication. The processing unit 702 then outputs an authentication result or an image of a captured fingerprint to the display unit 704.

The fingerprint authentication device 700 described above can also be a device that performs not only authentication of a fingerprint, but also authentication of a vein of a user.

Next, the face authentication device 710 according to the present embodiment will be explained, referring to FIG. 9. The face authentication device 710 is a device that performs face authentication, and includes the solid-state imaging apparatus 1 according to the present embodiment as an imaging unit that images a face. Furthermore, the face authentication device 710 includes, similarly to the fingerprint authentication device 700 described above, the processing unit 702 and the display unit 704. The processing unit 702 is a device that performs authentication with respect to a face image captured by the solid-state imaging apparatus 1, and is implemented, for example, by a personal computer. Moreover, the display unit 704 is a device that displays a face image captured by the solid-state imaging apparatus 1 or an authentication result, and is implemented, for example, by a CRT display device, and the like. Because operations of the face authentication device 710 are approximately the same as those of the fingerprint authentication device 700 described above, detailed explanation is omitted herein. Moreover, the face authentication device 700 described above can also be a device that performs not only authentication of a face, but also authentication of an iris.

The solid-state imaging apparatus 1 according to the present embodiment is capable of imaging a subject that is positioned close to the solid-state imaging apparatus 1, such as a fingerprint of the finger 900. Therefore, according to the present embodiment, for example, the solid-state imaging apparatus 1 of, for example, an authentication device that performs fingerprint authentication/iris authentication/vein authentication and face authentication at the same time can be provided.

Furthermore, a case in which the solid-state imaging apparatus 1 is applied to a research observation device of a sample 904, such as a cell, will be explained, referring to FIG. 10. Specifically, the solid-state imaging apparatus 1 according to the present embodiment can be applied to a device that observes the sample 904, such as a cell, mounted on a cover glass 402 from a position close thereto. As illustrated in FIG. 10, the solid-state imaging apparatus 1 according to the present embodiment can be arranged to be in contact with the cover glass 402 on which the sample 904 is placed. The solid-state imaging apparatus 1 thus arranged can function as a microscope without an object lens, and enables precise observation of the sample 904 even though it has a simple configuration. In other words, the solid-state imaging apparatus 1 described above can function as a research or a medical observation device, such as a lensless microscope, to determine, screen, and separate a cell, a virus, and the like. Note that the cover glass 402 is not limited to be of a glass material, but may be of a polyethylene terephthalate (PET) resin or the like, as long as it is made of a transparent material.

Moreover, in the present embodiment, an optical element, such as a bandpass filter, may be provided in front or rear of the cover glass 400, between or near respective micro lenses, or the like.

The solid-state imaging apparatus 1 according to the present embodiment is not limited to be applied to the fingerprint authentication device 700, the face authentication device 710, and the research observation device described above. For example, the solid-state imaging apparatus 1 according to the present embodiment can be applied to various electronic devices including a vein authentication device to perform vein authentication, an iris authentication device to perform iris authentication, a research or a medical observation device, such as a lensless microscope, to determine or separate a cell or a virus, various kinds of inspection devices that are used for an inspection of semiconductors and glasses, and a contact copy machine, and the like.

### 7. Sixth Embodiment

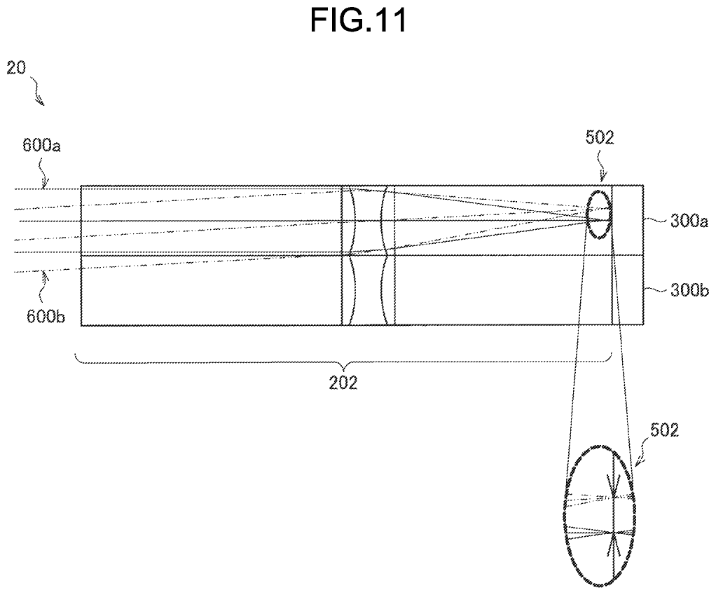

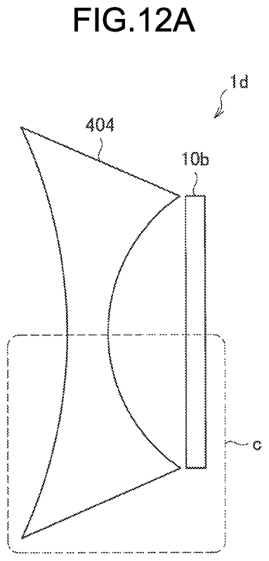

Next, a solid-state imaging apparatus 1d according to a sixth embodiment of the present disclosure will be explained, referring to FIG. 1, FIG. 12A, and FIG. 12B. FIG. 12A is a cross-sectional schematic diagram of the solid-state imaging apparatus 1d according to the present embodiment. Moreover, FIG. 12B is an enlarged view of a section c of FIG. 12A. In the present embodiment, unlike the first embodiment described above, a biconcave lens 404 (lens having concave surfaces on both sides) is used in place of the cover glass 400. Furthermore, in the present embodiment, the pixel 10b is arranged across space (space filled with atmosphere) from the biconcave lens 404. Moreover, in the present embodiment, the pixel 10b is constituted of a light guiding unit 200c without the transparent body 210, and the solid-state imaging device 300, unlike the pixel 10 of the first embodiment illustrated in FIG. 1.

In the present embodiment, as illustrated in FIG. 12A, plural pieces of the pixels 10d are aligned, and on the plural pixels 10b on the subject side, the biconcave lens 404 is arranged. The biconcave lens 404 is, namely, a lens having a negative power. In the present embodiment, by using the biconcave lens 404 having negative power as described, necessity of precise positioning is eliminated, and light can be effectively collected to the pixels 10b without drastically bending the light. Specifically, the biconcave lens 404 is a lens having a spherical surface of a curvature radius of −9 mm, a lens center thickness of 0.33 mm, and a curvature radius of 3.47 mm, and can be a plastic biconcave lens equivalent to ZEONEX z300r by Zeon Corporation. In the present embodiment, the biconcave lens 404 may be a diffraction grating instead of the lens having a negative power. Moreover, in the present embodiment, the pixel 10b is arranged at a distance by 0.71 mm from the center of the biconcave lens 404 on the pixel side.

As illustrated in FIG. 12B, for example, 13 pieces of the pixels 10b are aligned in a vertical direction, and optical axes passing through the center of an angle of view of the respective pixels 10b are inclined at −29.5°, −22.5°, −17.1°, −12.3°, −7.9°, −3.9°, 0°, 3.9°, 7.9°, 12.3°, 17.1°, 22.5°, 29.5° relative to an optical axis (the optical axis is perpendicular to the imaging device surface) passing through the center of the angle of view of the pixel 10b that is positioned at the center of the imaging device surface 502. In the present embodiment, by giving inclinations as described above, the solid-state imaging apparatus 1d having a desirable angle of view as a whole with the plural pixels 10b can be configured. For example, the length of one side of the imaging device surface 502 on which the plural solid-state imaging devices 300 are aligned is approximately 1.122 mm. The surface of the solid-state imaging apparatus 1d according to the present embodiment is similar to the surface of the first solid-state imaging apparatus 1 explained with reference to FIG. 4 and, therefore, explanation of the surface of the solid-state imaging apparatus 1d according to the present embodiment is omitted herein.

Moreover, if the solid-state imaging apparatus 1d is explained with reference to FIG. 1, unlike the pixel 10 of the first embodiment illustrated in FIG. 1, it is constituted of the light guiding unit 200c without the transparent body 210, and the solid-state imaging device 300. Specifically, the light guiding unit 200c includes the lens group 220 having a positive optical power, the light shielding unit 240, and the lens group 250 having a positive optical power, toward the solid-state imaging device 300 side from the subject side.

More specifically, in the present embodiment, the lens group 220 includes the micro lens 222 having a convex shape toward the solid-state imaging device 300 side, the micro lens 226 having a convex shape toward the subject side, and the transparent body 224 that is arranged between the micro lens 222 and the micro lens 226. More specifically, the micro lens 222 is made of, for example, a lens material having a d-line refractivity of 1.9 and a thickness of 5 μm, and a curvature of the lens is −15 μm. The micro lens 226 is made of, for example, a lens material having a d-line refractivity of 1.9 and a thickness of 1 μm, and a curvature of the lens is 15 μm. Moreover, the transparent body 224 is a transparent body having a d-line refractivity of 1.48 and a thickness of 3 μm. The micro lenses 222, 226 may be implemented by a diffraction element, or the like.

Moreover, the light guiding unit 200c includes the transparent body 230 between the lens group 220 and the lens group 250. Specifically, the transparent body 230 is, for example, a transparent body having a d-line refractivity of 1.55 and a length of 50 μm. Moreover, in the transparent body 230, the light shielding unit 240 described above is provided. The light shielding unit 240 is an open light shielding body having the opening portion 240a at a center as explained previously.

Furthermore, the lens group 250 includes a micro lens 252 having a convex shape toward the solid-state imaging device 300 side, a micro lens 256 having a convex shape toward the subject side, and a transparent body 254 that is arranged between the micro lens 252 and the micro lens 256. More specifically, the micro lens 252 is made of, for example, a lens material having a d-line refractivity of 1.9 and a thickness of 1 μm, and a curvature of the lens is −6 μm. The micro lens 256 is made of, for example, a lens material having a d-line refractivity of 1.9 and a thickness of 1 μm, and a curvature of the lens is 6 μm. Moreover, the transparent body 254 is, for example, a transparent body having a d-line refractivity of 1.48 and a thickness of 2 μm. The micro lenses 252, 256 may be implemented by a diffraction element or the like.

Furthermore, the light guiding unit 200c includes a transparent body 260 between the lens group 250 and the solid-state imaging device 300. Specifically, the transparent body 260 is, for example, a transparent body having a d-line refractivity of 1.55 and a length of 20.1 μm.

As described above, according to the present embodiment, by using the biconcave lens 404 having a negative power as described, necessity of precise positioning is eliminated, and light can be collected effectively to the pixels 10b without drastically bending the light.

### 8. Seventh Embodiment

Next, the solid-state imaging apparatus 1d according to a seventh embodiment of the present disclosure, which is a modification of the biconcave lens 404, will be explained, referring to FIG. 12A and FIG. 12B. In the present embodiment, the biconcave lens 404 that is different from the sixth embodiment described above, but the pixels 10b are common to the sixth embodiment.

In the present embodiment, as illustrated in FIG. 12A, the pixels 10d are aligned, and the biconcave lens 404 is arranged on the plural pixels 10b on the subject side. The biconcave lens 404 is, namely, a lens having a negative power. In the present embodiment also, by using the biconcave lens 404 having negative power as described, necessity of precise positioning is eliminated, and light can be effectively collected to the pixels 10b without drastically bending the light. Specifically, the biconcave lens 404 is a lens having a spherical surface of a curvature radius of −13.2 mm, a lens center thickness of 0.33 mm, and a curvature radius of 5 mm, and can be a glass biconcave lens equivalent to TAFD55 by HOYA Corporation. Moreover, in the present embodiment, the pixel 10b is arranged at a distance by 0.71 mm from the center of the biconcave lens 404 on the pixel side.

As illustrated in FIG. 12B, for example, 13 pieces of the pixels 10b are aligned in a vertical direction, and optical axes passing through the center of an angle of view of the respective pixels 10b are inclined at −38.3°, −29.5°, −22.8°, 16.7°, −10.8°, 5.3°, 0°, 5.3°, 10.8°, 16.7°, 22.8°, 29.8°, 38.3° relative to an optical axis (the optical axis is perpendicular to the imaging device surface) passing through the center of the angle of view of the pixel 10b that is positioned at the center of the imaging device surface 502. In the present embodiment, by giving inclinations as described above, the solid-state imaging apparatus 1d having a desirable angle of view as a whole with the plural pixels 10b can be configured. For example, the length of one side of the imaging device surface 502 on which the plural solid-state imaging devices 300 are aligned is approximately 0.912 mm. The surface of the solid-state imaging apparatus 1d according to the present embodiment is similar to the surface of the first solid-state imaging apparatus 1 explained with reference to FIG. 4 and, therefore, explanation of the surface of the solid-state imaging apparatus 1d according to the present embodiment is omitted herein.

As described above, according to the present embodiment, by using the biconcave lens 404 having a negative power as described, necessity of precise positioning is eliminated, and light can be collected effectively to the pixels 10b without drastically bending the light.

In the sixth and the seventh embodiments described above, the biconcave lens 404, namely, a lens having a negative power has been explained to be implemented by a single piece of lens. However, in these embodiments, the lens having a negative power is not limited to be implemented by a single piece of lens, and may be implemented by two or more pieces of lens, and is not particularly limited.

### 9. Eighth Embodiment

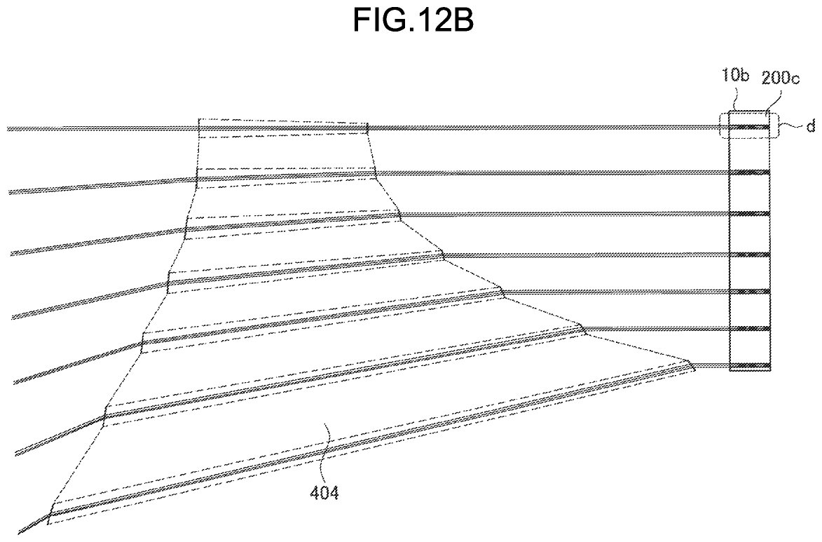

Moreover, in the present embodiment, a configuration of the pixels can be modified. For example, a modification of the pixels 10 will be explained as an eighth embodiment of the present invention, referring to FIG. 13. FIG. 13 is a schematic diagram of a pixel 10c according to the present embodiment.

As illustrated in FIG. 13, while the lens groups 220, 250 in the light guiding unit 200 are implemented by two pieces of micro lenses in the first embodiment described above, in a light guiding unit 200d having the pixel 10c of the present embodiment, it may be implemented by one piece of micro lenses 228, 258 instead of the lens groups 220, 250. In the present embodiment, by using such a structure, the number of parts can be reduced, and increase of manufacturing cost of a solid-state imaging apparatus 1e can be suppressed.

In the present embodiment, one out of the lens groups 220, 250 of the light guiding unit 200 may be implemented by two pieces of micro lenses, and the other one may be implemented by one piece of micro lenses, or may be implemented by three or more micro lenses, and it is not particularly limited.

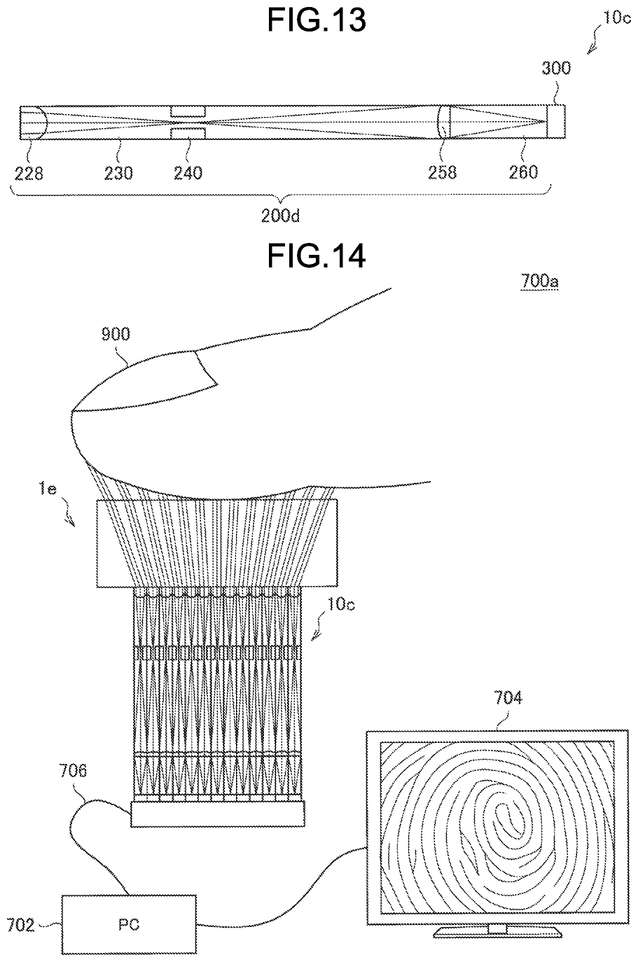

Moreover, as illustrated in FIG. 14 that is a schematic diagram of a fingerprint authentication device 700a according to the present embodiment, the solid-state imaging apparatus 1e using the pixel 10c can be applied to the fingerprint authentication device 700a. Although it is illustrated as the cover glass 400 is present between the solid-state imaging apparatus 1e and the finger 900 in FIG. 14, the present embodiment is not limited to a configuration example illustrated in FIG. 14. In the present embodiment, for example, the lens having a negative power (biconcave lens 404) on the subject side in the sixth and the seventh embodiments may be used in place of the cover glass 400, or it may be configured to be in contact directly with the finger 900 without having the cover glass 400 or the lens having a negative power in between.

As described above, according to the present embodiment, the number of parts can be reduced, and increase of manufacturing cost of the solid-state imaging apparatus 1e can be suppressed.

### 10. Conclusion

As described above, according to the embodiments of the present disclosure, the use efficiency of incident light can be improved while avoiding overlap of angles of view of the adjacent pixels 10.

Furthermore, by using the solid-state imaging apparatus 1 or the electronic device according to the embodiments of the present disclosure, for example, effects described below are produced. It is needless to say that effects produced by use of the solid-state imaging apparatus 1 or the electronic device according to the present embodiments are not limited to the example described below.

(1) According to an embodiment of the present disclosure, the use efficiency of incident light can be improved in a solid-state imaging apparatus that uses a micro lens having a surface size of the same level as a unit pixel of a solid-state imaging device, and having a total length of 1 mm or smaller without using an imaging lens (object lens).
(2) According to an embodiment of the present disclosure, it becomes possible to manufacture, at low cost, a solid-state imaging apparatus to detect an infrared ray that is difficult to use a general imaging lens.
(3) According to an embodiment of the present disclosure, because an imaging lens is not used, a solid-state imaging apparatus without chromatic aberration can be provided
(4) According to an embodiment of the present disclosure, because a solid-state imaging apparatus can be manufactured in a semiconductor manufacture process, manufacture of a solid-state imaging apparatus and an electronic device including the same at low cost is enabled.
(5) According to an embodiment of the present disclosure, because imaging of a subject that is closely positioned is possible, a subject on a cover glass of a solid-state imaging apparatus or a cover glass arranged close to the solid-state imaging apparatus can be imaged. Therefore, according to an embodiment of the present disclosure, for example, a solid-state imaging apparatus of an authentication device that performs fingerprint authentication/iris authentication/vein authentication and face authentication at the same time can be provided.
(6) According to an embodiment of the present disclosure, a lensless microscope that can be used, for example, for screening of cells, determination of viruses, and the like can be provided.

In the embodiments of the present disclosure, the solid-state imaging device 300 described above can be a CCD image sensor or a CMOS image sensor.

### 11. Supplement

As above, exemplary embodiments of the present disclosure have been explained with reference to the accompanying drawings, but a technical scope of the present disclosure is not limited to the example. It is obvious that those who have common knowledge in a technical field of the present disclosure can think of various alteration examples and correction examples within a scope of the technical idea described in claims, and these are also understood to naturally belong to the technical scope of the present disclosure.

Moreover, the effects described in the present application are only an explanatory or exemplary, and are not limited. That is, the technique according to the present disclosure can produce other effects obvious to those skilled in the art from the description of the present application, in addition to the effects described above or in place of the effects described above.

Following configurations also belong to the technical scope of the present disclosure.

(1)

A solid-state imaging apparatus comprising
a plurality of pixels that are arranged in a matrix shape on an imaging device surface, wherein
each of the pixels includes
   at least one solid-state imaging device; and
   at least one light guiding unit that is arranged on a subject side of the solid-state imaging device,
the light guiding unit includes
   a first transparent body;
   a first lens group having a positive optical power;
   a light shielding unit having an opening portion; and
   a second lens group having a positive optical power, sequentially toward a solid-state imaging device side from the subject side along a light guiding direction of the light guiding unit.
      (2)

The solid-state imaging apparatus according to (1), wherein
the light guiding unit is a Keplerian optical system that has a focal point between the first lens group and the second lens group, and
the opening portion of the light shielding unit is arranged to overlap the focal point.
   (3)

The solid-state imaging apparatus according to (2), wherein
a focal length fg₁ of the first lens group, a focal length fg₂ of the second lens group, and a distance L between the first lens group and the second lens group satisfy a condition expression (a) below.

L>(fg₁+fg₂)/2 (a)

(4)

The solid-state imaging apparatus according to (3), wherein
a range of an angle θ formed between an upper light beam and a lower light beam entering the pixel that is positioned at a center of the imaging device surface satisfies a condition expression (b) below.

−10°≤θ≤10° (b)

In the condition expression (b) above, a light collecting direction takes a negative value, and a light diffusing direction takes a positive value.

(5)

The solid-state imaging apparatus according to (3) or (4), wherein
the focal length fg₂ of the second lens group satisfies a condition expression (c) below.

3 mm>fg₂>0.0005 mm (c)

(6)

The solid-state imaging apparatus according to any one of (1) to (5), wherein
the first lens group includes a first micro lens having a convex shape toward the solid-state imaging device side.
   (7)

The solid-state imaging apparatus according to (6), wherein
a surface of the first micro lens on the solid-state imaging device side has a different angle relative to the imaging device surface in each of the pixels.
   (8)

The solid-state imaging apparatus according to (6) or (7), wherein
the first lens group includes
   the first micro lens; and
   the second micro lens having a convex shape toward the subject side, sequentially toward the solid-state imaging device side from the subject side along the light guiding direction of the light guiding unit.
      (9)

The solid-state imaging apparatus according to (8), wherein
the first lens group further includes a fourth transparent body that is arranged between the first micro lens and the second micro lens.
   (10)

The solid-state imaging apparatus according to any one of (1) to (9), wherein
a surface of the first transparent body on the subject side has a different angle relative to the imaging device surface in each of the pixels.
   (11)

The solid-state imaging apparatus according to (10), wherein
a plurality of the first transparent body are a lens formed in one piece.
   (12)

The solid-state imaging apparatus according to (11), wherein
the lens has a concave shape on a surface on the subject side.
   (13)

The solid-state imaging apparatus according to (1), wherein
the first transparent body has a lens having a negative optical power.
   (14)

The solid-state imaging apparatus according to (13), wherein
the lens is a biconcave lens having a concave surface on both sides.
   (15)

The solid-state imaging apparatus according to (14), wherein
between the lens and the first lens group, space filled with atmosphere is present.
   (16)

The solid-state imaging apparatus according to any one of (1) to (12), wherein
the second lens group includes a third micro lens having a convex shape toward the subject side.
   (17)

The solid-state imaging apparatus according to (16), wherein
the second lens group includes
   a fourth micro lens having a convex shape toward the solid-state imaging device; and
   a third micro lens, sequentially toward the solid-state imaging device side from the subject side along the light guiding direction of the light guiding unit.
      (18)

The solid-state imaging apparatus according to (17), wherein
the second lens group further includes a fifth transparent body that is arranged between the fourth micro lens and the third micro lens.
   (19)

The solid-state imaging apparatus according to any one of (1) to (12) further includes a cover glass that is arranged on a surface of the plural first transparent bodies on the subject side, in a shared manner among the plural pixels.

(20)

In the solid-state imaging apparatus according to any one of (1) to (12), wherein
the light guiding unit further includes a second transparent body between the first lens group and the second lens group.
   (21)

In the solid-state imaging apparatus according to any one of (1) to (12), wherein
the light guiding unit further includes a third transparent body between the second lens group and the solid-state imaging device.
   (22)

An electronic device comprising a solid-state imaging apparatus that includes a plurality of pixels arranged in a matrix shape on an imaging device surface, wherein
each of the pixels includes
   at least one solid-state imaging device; and
   at least one light guiding unit that is arranged on a subject side of the solid-state imaging device,
the light guiding unit includes
   a first transparent body;
   a first lens group having a positive optical power;
   a light shielding unit having an opening portion; and
   a second lens group having a positive optical power, sequentially toward a solid-state imaging device side from the subject side along a light guiding direction of the light guiding unit.

### REFERENCE SIGNS LIST

1, 1a, 1b, 1c, 1d, le SOLID-STATE IMAGING APPARATUS
10, 10a, 10b, 10c, 20 PIXEL
200, 200a, 200b, 200c, 202 LIGHT GUIDING UNIT
210, 210a, 210b, 210c, 224, 230, 254, 260 TRANSPARENT BODY
220, 250 LENS GROUP
222, 222a, 226, 228, 252, 256, 256a, 258 MICRO LENS
240 LIGHT SHIELDING UNIT
240a OPENING PORTION
300, 300a, 300b SOLID-STATE IMAGING DEVICE
400, 402 COVER GLASS
404 BICONCAVE LENS
500 IMAGE FORMING POSITION
502 IMAGING DEVICE SURFACE
504 ARROW
600a, 600b INCIDENT LIGHT
700, 700a FINGERPRINT AUTHENTICATION DEVICE
702 PROCESSING UNIT
704 DISPLAY UNIT
706 DATA LINE
710 FACE AUTHENTICATION DEVICE
900 FINGER
902 FACE
904 SAMPLE
a, b, c, d SECTION

1. A solid-state imaging apparatus comprising
a plurality of pixels that are arranged in a matrix shape on an imaging device surface, wherein
each of the pixels includes
at least one solid-state imaging device; and
at least one light guiding unit that is arranged on a subject side of the solid-state imaging device,
the light guiding unit includes
a first transparent body;
a first lens group having a positive optical power;
a light shielding unit having an opening portion; and
a second lens group having a positive optical power, sequentially toward a solid-state imaging device side from the subject side along a light guiding direction of the light guiding unit.

2. The solid-state imaging apparatus according to claim 1, wherein
the light guiding unit is a Keplerian optical system that has a focal point between the first lens group and the second lens group, and
the opening portion of the light shielding unit is arranged to overlap the focal point.

3. The solid-state imaging apparatus according to claim 2, wherein
a focal length fg₁ of the first lens group, a focal length fg₂ of the second lens group, and a distance L between the first lens group and the second lens group satisfy a condition expression (a) below.
L>(fg₁+fg₂)/2 (a)

4. The solid-state imaging apparatus according to claim 3, wherein
a range of an angle θ formed between an upper light beam and a lower light beam entering the pixel that is positioned at a center of the imaging device surface satisfies a condition expression (b) below.
−10°≤θ≤10° (b)
In the condition expression (b) above, a light collecting direction takes a negative value, and a light diffusing direction takes a positive value.

5. The solid-state imaging apparatus according to claim 3, wherein
the focal length fg₂ of the second lens group satisfies a condition expression (c) below,
3 mm<fg₂>0.0005 mm (c)

6. The solid-state imaging apparatus according to claim 1, wherein
the first lens group includes a first micro lens having a convex shape toward the solid-state imaging device side.

7. The solid-state imaging apparatus according to claim 6, wherein
a surface of the first micro lens on the solid-state imaging device side has a different angle relative to the imaging device surface in each of the pixels.

8. The solid-state imaging apparatus according to claim 6, wherein
the first lens group includes
the first micro lens; and
the second micro lens having a convex shape toward the subject side, sequentially toward the solid-state imaging device side from the subject side along the light guiding direction of the light guiding unit.

9. The solid-state imaging apparatus according to claim 8, wherein
the first lens group further includes a fourth transparent body that is arranged between the first micro lens and the second micro lens.

10. The solid-state imaging apparatus according to claim 1, wherein
a surface of the first transparent body on the subject side has a different angle relative to the imaging device surface in each of the pixels.

11. The solid-state imaging apparatus according to claim 10, wherein
a plurality of the first transparent body are a lens formed in one piece.

12. The solid-state imaging apparatus according to claim 11, wherein
the lens has a concave shape on a surface on the subject side.

13. The solid-state imaging apparatus according to claim 1, wherein
the first transparent body has a lens having a negative optical power.

14. The solid-state imaging apparatus according to claim 13, wherein
the lens is a biconcave lens having a concave surface on both sides.

15. The solid-state imaging apparatus according to claim 14, wherein
between the lens and the first lens group, space filled with atmosphere is present.

16. The solid-state imaging apparatus according to claim 1, wherein
the second lens group includes a third micro lens having a convex shape toward the subject side.

17. The solid-state imaging apparatus according to claim 16, wherein
the second lens group includes
a fourth micro lens having a convex shape toward the solid-state imaging device; and
a third micro lens, sequentially toward the solid-state imaging device side from the subject side along the light guiding direction of the light guiding unit.

18. The solid-state imaging apparatus according to claim 17, wherein
the second lens group further includes a fifth transparent body that is arranged between the fourth micro lens and the third micro lens.

19. An electronic device comprising a solid-state imaging apparatus that includes a plurality of pixels arranged in a matrix shape on an imaging device surface, wherein
each of the pixels includes
at least one solid-state imaging device; and
at least one light guiding unit that is arranged on a subject side of the solid-state imaging device,
the light guiding unit includes
a first transparent body;
a first lens group having a positive optical power;
a light shielding unit having an opening portion; and
a second lens group having a positive optical power, sequentially toward a solid-state imaging device side from the subject side along a light guiding direction of the light guiding unit.
